(19) United States
(12) Patent Application Publication
(10) Pub. No.: US 2020/0225279 A1
(43) Pub. Date: Jul. 16, 2020

(54) SMART DECISION FEEDBACK DEVICE AND METHOD FOR INSPECTING CIRCUIT BOARD

(71) Applicant: HONGFUJIN PRECISION ELECTRONICS (TIANJIN) CO.,LTD., Tianjin (CN)

(72) Inventors: QIAO-ZHONG ZHAO, Tianjin (CN); SHIH-LIN WU, New Taipei (TW)

(21) Appl. No.: 16/260,421

(22) Filed: Jan. 29, 2019

(30) Foreign Application Priority Data
Jan. 10, 2019 (CN) 201910024497.3

(51) Int. Cl. G01R 31/28; G01R 31/04; G01N 21/956; H05K 13/08; H05K 1/02

(52) U.S. Cl. CPC G01R 31/2812; G01R 31/048; H05K 1/0266; G01N 21/95684; H05K 13/0817; G01R 31/2815

(57) ABSTRACT

A smart decision feedback method for inspecting a circuit board includes obtaining a number of abnormal solder paste points of a circuit board identified by a solder paste inspection device, determining whether the number of abnormal solder paste points is greater than or equal to a first predetermined value, determining whether an identification result of the solder paste inspection device is abnormal when the number of abnormal solder paste points is less than the first predetermined value, obtaining an inspection result performed by a testing device inspecting the circuit board when the identification result of the solder paste inspection device is abnormal, analyzing an adjustment parameter of the solder paste inspection device, and sending the adjustment parameter to the solder paste inspection device. A first prompt is displayed when the number of abnormal solder paste points is greater than or equal to the first predetermined value.

### FIELD

The subject matter herein generally relates to circuit boards, and more particularly to a smart decision feedback device and a method thereof for inspecting a circuit board.

### BACKGROUND

Generally, electronic components mounted by surface mount technology (SMT) on printed circuit boards are mounted by solder paste, and the solder paste is inspected by a solder paste inspection device. An abnormality of solder paste printing on the circuit board is initially determined by the solder paste inspection device, and then visually inspected to determine whether the solder paste printing is abnormal. Parameter corrections and debugging of the solder paste inspection machine are accomplished by the personnel on site, which results in high labor cost and may be inefficient.

### BRIEF DESCRIPTION OF THE DRAWINGS

Implementations of the present disclosure will now be described, by way of embodiments, with reference to the attached figures.

FIG. 1 is a flowchart of an embodiment of a smart decision feedback method for inspecting a circuit board.

FIG. 2 is a flowchart of an embodiment of a method of determining whether an inspection result of a solder paste inspection device is abnormal.

FIG. 3 is a block diagram of a smart decision feedback device.

FIG. 4 is a block diagram of a smart decision feedback system implemented by the smart decision feedback device.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-ended inclusion or membership in a so-described combination, group, series and the like.

In general, the word “module” as used hereinafter refers to logic embodied in hardware or firmware, or to a collection of software instructions, written in a programming language such as, for example, Java, C, or assembly. One or more software instructions in the modules may be embedded in firmware such as in an erasable-programmable read-only memory (EPROM). It will be appreciated that the modules may comprise connected logic units, such as gates and flip-flops, and may comprise programmable units, such as programmable gate arrays or processors. The modules described herein may be implemented as either software and/or hardware modules and may be stored in any type of computer-readable medium or other computer storage device.

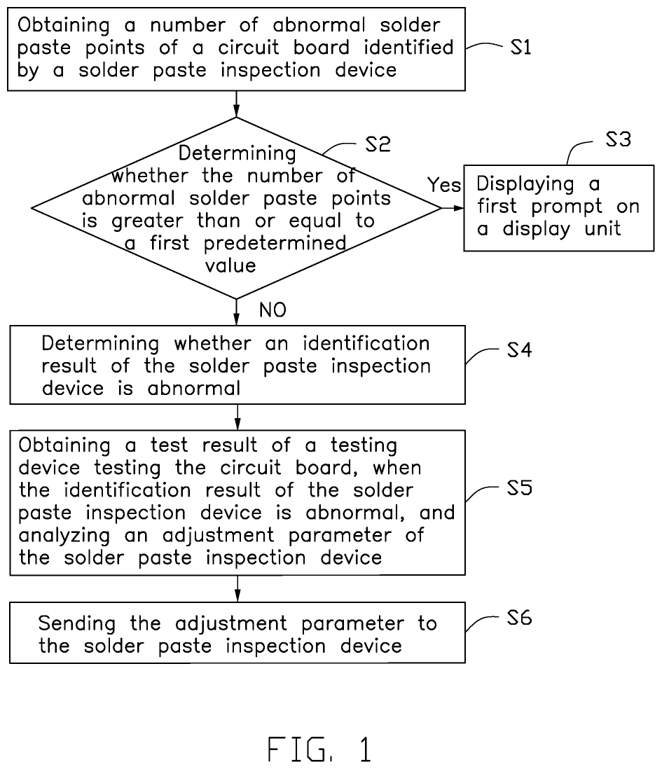

FIG. 1 shows an embodiment of a smart decision feedback method for inspecting a solder paste printed circuit board in combination with a solder paste inspection device, combining AOI, ICT, and FVS test results, and automatically sending feedback of parameters required to adjust the solder paste inspection device, thereby improving accuracy of the inspection results of the circuit board. The smart decision feedback method may begin at block S1.

At block S1, a number of abnormal solder paste points of the circuit board identified by the solder paste inspection device is obtained.

At block S2, whether the number of abnormal solder paste points is greater than or equal to a first predetermined value is determined. When the number of abnormal solder paste points is greater than or equal to the first predetermined value, block S3 is implemented. If the number of abnormal solder paste points is less than the first predetermined value, block S4 is implemented.

At block S3, a first prompt is displayed on a display unit.

At block S4, whether an identification result of the solder paste inspection device is abnormal is determined.

At block S5, when the identification result of the solder paste inspection device is abnormal, a test result performed by a testing device on the circuit board is obtained, and an adjustment parameter of the solder paste inspection device is analyzed.

At block S6, the adjustment parameter is sent to the solder paste inspection device.

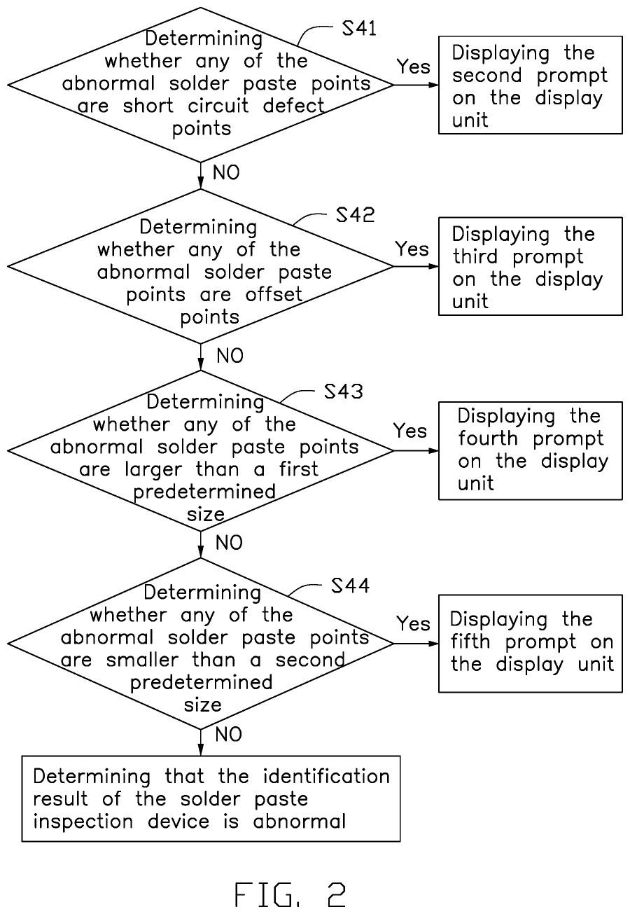

FIG. 2 shows a flowchart of a method for determining whether the identification result of the solder paste inspection device is abnormal in block S4 in FIG. 1. The method may begin at block S41.

At block S41, whether any of the abnormal solder paste points include a short circuit defect point is determined. If any of the abnormal solder paste points include a short circuit defect point, the second prompt is displayed on the display unit. If none of the abnormal solder paste points include a short circuit defect point, block S42 is implemented.

When the abnormal solder paste point includes a short circuit defect point, the second prompt is used to prompt a relevant personnel to wash or repair the circuit board. After the circuit board is washed, the circuit board can be re-printed by a printing machine, and the repaired circuit board can be inspected by the solder paste inspection device again.

Furthermore, when the abnormal solder paste points include a short circuit defect point, it is further determined whether a number of the short circuit defect points is greater than or equal to a second predetermined value. If the number of the short circuit defect points is greater than or equal to the second predetermined value, the second prompt includes a prompt to wash the circuit board. If the number of the short circuit defect points is less than the second predetermined value, the second prompt includes a prompt to overhaul the circuit board. In one embodiment, the second predetermined value is 5. In other embodiments, the second predetermined value may be adjusted according to actual requirements.

At block S42, whether any of the abnormal solder paste points include an offset point is determined. If any of the abnormal solder paste points include an offset point, the third prompt is displayed on the display unit. If none of the abnormal solder paste points include an offset point, block S43 is implemented.

The offset point is defined as the abnormal solder paste point having an offset surface area greater than or equal to 60% of a standard surface area. The third prompt includes a prompt to wash the circuit board. A criterion for determining the offset points may be adjusted to a different percentage of the standard surface area according to actual requirements. After the relevant personnel views the third prompt, the circuit board is washed, and the circuit board is re-printed by the printing machine.

At block S43, whether any of the abnormal solder paste points is larger than a first predetermined size is determined. If any of the abnormal solder paste points is larger than the first predetermined size, the fourth prompt is displayed on the display unit. If none of the abnormal solder paste points is larger than the first predetermined size, block S44 is implemented.

The abnormal solder paste point is determined to be larger than the first predetermined size when a surface area of the abnormal solder paste point is greater than or equal to 250% of a standard volume. The fourth prompt includes a prompt to wash the circuit board. A criterion for determining that the abnormal solder paste point is larger than the first predetermined size may be adjusted to a different percentage of the standard surface area according to actual requirements. After the relevant personnel views the fourth prompt, the circuit board is washed, and the circuit board is re-printed by the printing machine.

At block S44, whether any of the abnormal solder paste points is smaller than a second predetermined size is determined. If any of the abnormal solder paste points is smaller than the second predetermined size, the fifth prompt is displayed on the display unit. If none of the abnormal solder paste points is smaller than the second predetermined size, the identification result of the solder paste inspection device is determined to be abnormal.

When the abnormal solder paste point is determined to be smaller than the second predetermined size, the fifth prompt is used to prompt the relevant personnel to wash or repair the circuit board. The circuit board after washing can be re-printed by the printing machine, and the re-printed or repaired circuit board can be inspected by the solder paste inspection device again.

Furthermore, when any of the abnormal solder paste points is smaller than the second predetermined size, it is further determined whether a number of the solder paste points smaller than the second predetermined size is greater than or equal to a third predetermined value. If the number of the solder paste points smaller than the second predetermined size is greater than or equal to the third predetermined value, the fifth prompt includes a prompt to wash the circuit board. In one embodiment, the third predetermined value is 5. In other embodiments, the third predetermined value may be adjusted according to actual requirements.

In blocks S2 and S3, when the number of abnormal solder paste points is greater than or equal to the first predetermined value, the first prompt is used to prompt a relevant personnel to manually determine whether there is a problem of misidentification of the abnormal solder paste point or a problem of the solder paste inspection device. In one embodiment, a problem of the solder paste inspection device may be an incorrect template of the solder paste points on the circuit board. If there is a problem of incorrect identification of the abnormal solder paste points, the solder paste inspection device is adjusted to identify the abnormal solder paste points. If there is a problem of the template of the solder paste points, the template of the solder paste points is adjusted.

In one embodiment, the first predetermined value is 200. In other embodiments, the first predetermined value may be adjusted according to actual conditions. For example, the first predetermined value cannot be greater than a total number of solder paste points on the circuit board.

It other embodiments, a sequence of determining a type of abnormality of the solder paste points as described in FIG. 2 may be changed according to actual requirements.

In block S5 in FIG. 1, the inspection result obtained from the testing device is at least one of an Automated Optical Inspection (AOI), an In-Circuit-Test (ICT), and a Function Verification Test (FVS) test result. When the identification result of the solder paste inspection device is judged to be abnormal, by examining the circuit board with the abnormal identification result, it is possible to analyze a cause of the abnormality of the identification result of the solder paste inspection device, thereby analyzing the parameters of the solder paste inspection device that need to be adjusted. Therefore, at block S6, the adjustment parameters are sent to the solder paste inspection device to facilitate self-adjustment of the solder paste inspection device to improve accuracy of subsequent recognition results.

In addition, AOI, ICT and FVS test the circuit board according to different principles. Thus, the inspection results are more comprehensive and accurate.

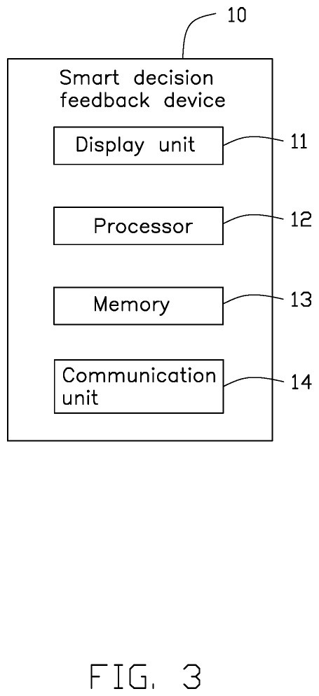

FIG. 3 shows an embodiment of a smart decision feedback device 10 capable of implementing the smart decision feedback method as described above. The smart decision feedback device 10 includes a display unit 11, a processor 12, a memory 13, and a communication unit 14. The display unit 11, the memory 13, and the communication unit 14 are electrically coupled to the processor 12. The smart decision feedback device 10 establishes communication with the solder paste inspection device via the communication unit 14.

The processor 12 may be a central processing unit (CPU), a digital signal processor, a single chip microcomputer, or the like. The memory 13 is capable of storing various types of data, such as program codes, in the smart decision feedback device 10, and achieves high speed and automatic access of programs or data during the operation of the smart decision feedback device 10.

The memory 13 can be, but is not limited to, a read only memory (ROM), a random access memory (RAM), a programmable read only memory (PROM), an erasable programmable read only memory (EPROM), a one-time programmable read only memory, (OTPROM), an electronically erasable rewritable read only memory (EEPROM), a compact disk read-only memory (CD-ROM), or other optical disk storage, disk storage, magnetic tape storage, or any computer readable medium for storing data.

In other embodiments, the smart decision feedback device 10 may not include the display unit 11, and instead couple to an external device with the display function to meet the requirement of displaying the prompts. In addition, the smart decision feedback device 10 may not include the communication unit 14, and instead have an external communication function to satisfy the demand for transmitting data or signals.

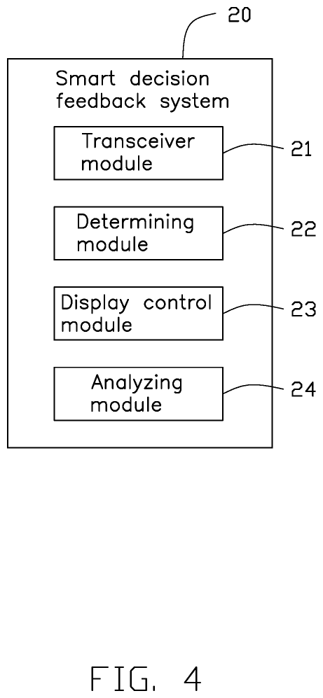

Referring to FIG. 4, a smart decision feedback system 20 implemented in the smart decision feedback device 10 is divided into a plurality of functional modules according to functions performed by the smart decision feedback system 20. The plurality of functional modules can include a transceiver module 21, a determination module 22, a display control module 23, and an analysis module 24.

The transceiver module 21 is configured to obtain the number of abnormal solder paste points on the circuit board identified by the solder paste inspection device. The determining module 22 is configured to sequentially determine whether the number of abnormal solder paste points is greater than or equal to a first predetermined value, whether any of the abnormal solder paste point is a short circuit defect point, whether any of the abnormal solder paste points is an offset point, whether any of the abnormal solder paste points is surface area, and whether any of the abnormal solder paste points is smaller than the second predetermined size. Then, it is determined whether the identification result of the solder paste inspection device 10 is abnormal.

The display control module 23 is configured to control the display unit 11 to display the first prompt when the number of the abnormal solder paste points is greater than or equal to the first predetermined value, display the second prompt when any of the abnormal solder paste points is a short circuit defect point, the third prompt when any of the abnormal solder paste points is an offset point, the fourth prompt when any of the abnormal solder paste points is surface area, and the fifth prompt when any of the abnormal solder paste points is smaller than the second predetermined size.

The transceiver module 21 is further configured to obtain a test result performed by the testing device on the circuit board when the identification result is abnormal. The test result obtained from the testing device is at least one of AOI, ICT, and FVS test results. The analysis module 24 analyzes the parameters to be adjusted by the solder paste inspection device according to the AOI, ICT and FVS test results when the determination module 22 determines that the identification result of the solder paste inspection device is abnormal. The transceiver module 21 is configured to send adjustment parameters to the solder paste inspection device.

In this embodiment, the first predetermined value is 200, the second predetermined value is 5, and the third predetermined value is 5. In other embodiments, the first predetermined value, the second predetermined value, and the third predetermined value can be adjusted according to actual requirements.

In one embodiment, the offset point is defined as the abnormal solder paste point having an offset surface area greater than or equal to 60% of a standard surface area, the surface area solder paste point is defined as the abnormal solder paste point having a surface area greater than or equal to 250% of a standard volume, and the solder paste point smaller than the second predetermined size is defined as the abnormal solder paste point having a surface area less than or equal to 30% of a standard volume.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A smart decision feedback method for inspecting a circuit board, the smart decision feedback method comprising:
obtaining a number of abnormal solder paste points of a circuit board identified by a solder paste inspection device;
determining whether the number of abnormal solder paste points is greater than or equal to a first predetermined value;
displaying, when the number of abnormal solder paste points is greater than or equal to the first predetermined value, a first prompt on a display unit;
determining, when the number of abnormal solder paste points is less than the first predetermined value, whether an identification result of the solder paste inspection device is abnormal;
obtaining, when the identification result of the solder paste inspection device is abnormal, an inspection result performed by a testing device inspecting the circuit board, and analyzing an adjustment parameter of the solder paste inspection device; and
sending the adjustment parameter to the solder paste inspection device.

2. The smart decision feedback method of claim 1, wherein the method of determining whether the identification result of the solder paste inspection device is abnormal comprises:
determining whether any of the abnormal solder paste points are short circuit defect points, and displaying a second prompt on the display unit when any of the abnormal solder paste points are short circuit defect points;
determining, when none of the abnormal solder paste points are short circuit defect points, whether any of the abnormal solder paste points are offset points, and displaying a third prompt on the display unit when any of the abnormal solder paste points are offset points;
determining, when none of the abnormal solder paste points are offset points, whether any of the abnormal solder paste points are larger than a first predetermined size, and displaying a fourth prompt on the display unit when any the abnormal solder paste points are larger than the first predetermined size; and
determining, when none of the abnormal solder paste points are larger than the first predetermined size, whether any of the abnormal solder paste points are smaller than a second predetermined size, and displaying a fifth prompt on the display unit when any of the abnormal solder paste points are smaller than the second predetermined size.

3. The smart decision feedback method of claim 1, wherein the identification result is at least one of an AOI, ICT, and FVS test result.

4. The smart decision feedback method of claim 2 further comprising determining, when any of the abnormal solder paste points are short circuit defect points, whether a number of the short circuit defect points is greater than or equal to a second predetermined value; wherein:
when the number of the short circuit defect points is greater than or equal to the second predetermined value, the second prompt comprises a prompt to wash the circuit board;
when the number of the short circuit defect points is less than the second predetermined value, the second prompt comprises a prompt to overhaul the circuit board.

5. The smart decision feedback method of claim 2, wherein:
the offset point is defined as the abnormal solder paste point having an offset surface area greater than or equal to 60% of a standard surface area; and
the third prompt comprises a prompt to wash the circuit board.

6. The smart decision feedback method of claim 2, wherein:
the first predetermined size is defined as the abnormal solder paste point having a surface area greater than or equal to 250% of a standard surface area; and
the fourth prompt comprises a prompt to wash the circuit board.

7. The smart decision feedback method of claim 2, further comprising determining, whether a number of the abnormal solder past points which are smaller than the second predetermined size is greater than or equal to a third predetermined value; wherein:
when the number of the abnormal solder paste points which are smaller than the second predetermined size is greater than or equal to the third predetermined value, displaying the fifth prompt comprising a prompt to wash the circuit board;
when the number of the abnormal solder paste points which are smaller than the second predetermined size is less than the third predetermined value, displaying the third prompt comprising a prompt to overhaul the circuit board.

8. The smart decision feedback method of claim 7, wherein the second predetermined size is defined as the abnormal solder paste point having a surface area less than or equal to 30% of a standard surface area.

9. The smart decision feedback method of claim 1, wherein the first predetermined value is 200.

10. A non-transitory storage medium having stored thereon instructions that, when executed by at least one processor of a computing device, causes the at least one processor to execute instructions of a smart decision feedback method for inspecting a circuit board, the smart decision feedback method comprising:
obtaining a number of abnormal solder paste points of a circuit board identified by a solder paste inspection device;
determining whether the number of abnormal solder paste points is greater than or equal to a first predetermined value, and displaying, when the number of abnormal solder paste points is greater than or equal to the first predetermined value, a first prompt on a display unit;
determining, when the number of abnormal solder paste points is less than the first predetermined value, whether an identification result of the solder paste inspection device is abnormal;
obtaining, when the identification result of the solder paste inspection device is abnormal, an inspection result performed by an testing device inspecting the circuit board, and analyzing an adjustment parameter of the solder paste inspection device; and
sending the adjustment parameter to the solder paste inspection device.

11. The non-transitory storage medium of claim 10, wherein determining whether the identification result of the solder paste inspection device is abnormal comprises:
determining whether any of the abnormal solder paste points are short circuit defect points, and displaying a second prompt on the display unit when any of the abnormal solder paste points are short circuit defect points;
determining, when none of the abnormal solder paste points are short circuit defect points, whether any of the abnormal solder paste points are offset points, and displaying a third prompt on the display unit when any of the abnormal solder paste points are offset points;
determining, when none of the abnormal solder paste points are offset points, whether any of the abnormal solder paste points are larger than a first predetermined size, and displaying a fourth prompt on the display unit when any the abnormal solder paste points are larger than the first predetermined size; and
determining, when none of the abnormal solder paste points are larger than the first predetermined size, whether any of the abnormal solder paste points are smaller than a second predetermined size, and displaying a fifth prompt on the display unit when any of the abnormal solder paste points are smaller than the second predetermined size.

12. The non-transitory storage medium of claim 10, wherein the identification result is at least one of an AOI, ICT, and FVS test result.

13. The non-transitory storage medium of claim 11, wherein:
the smart decision feedback method further comprises determining, when any of the abnormal solder paste points are short circuit defect points, whether a number of the short circuit defect points is greater than or equal to a second predetermined value;
when the number of the short circuit defect points is greater than or equal to the second predetermined value, the second prompt comprises a prompt to wash the circuit board;
when the number of the short circuit defect points is less than the second predetermined value, the second prompt comprises a prompt to overhaul the circuit board.

14. The non-transitory storage medium of claim 11, wherein:
the offset point is defined as the abnormal solder paste point having an offset surface area greater than or equal to 60% of a standard surface area; and
the third prompt comprises a prompt to wash the circuit board.

15. The non-transitory storage medium of claim 11, wherein:
the first predetermined size is defined as the abnormal solder paste point having a surface area greater than or equal to 250% of a standard surface area; and
the fourth prompt comprises a prompt to wash the circuit board.

16. The non-transitory storage medium of claim 11, wherein:
the smart decision feedback method further comprises determining, whether a number of the abnormal solder past points which are smaller than the second predetermined size is greater than or equal to a third predetermined value; wherein:
when the number of the abnormal solder paste points which are smaller than the second predetermined size is greater than or equal to the third predetermined value, displaying the fifth prompt comprising a prompt to wash the circuit board;
when the number of the abnormal solder paste points which are smaller than the second predetermined size is less than the third predetermined value, displaying the third prompt comprising a prompt to overhaul the circuit board.

17. The non-transitory storage medium of claim 16, wherein the point smaller than the second predetermined size is defined as the abnormal solder paste point having a surface area less than or equal to 30% of a standard surface area.

18. The non-transitory storage medium of claim 10, wherein the first predetermined value is 200.
